(19) United States
(12) Patent Application Publication
(10) Pub. No.: US 2025/0216479 A1
(43) Pub. Date: Jul. 3, 2025

(54) METHODS AND APPARATUSES FOR IDENTIFYING DEFECTIVE ELECTRICAL CONNECTIONS OF A SUBSTRATE

(71) Applicant: Applied Materials, Inc., Santa Clara, CA (US)

(72) Inventors: Bernhard G. MUELLER, Finsing (DE); Axel WENZEL, Augsburg (DE)

(21) Appl. No.: 18/848,601

(22) PCT Filed: May 10, 2022
(86) PCT No.: PCT/EP2022/062646

§ 371 Date: Sep. 19, 2024

(51) Int. Cl. G01R 31/66

(52) U.S. Cl. CPC G01R 31/66

(57) ABSTRACT

A method of identifying defective electrical connections of a substrate is provided, the substrate having a first surface contact and a first electrical connection extending from the first surface contact through the substrate. The method includes placing the substrate on a stage in a vacuum chamber; charging the first surface contact by directing an electron beam on the first surface contact and detecting secondary electrons emitted from the first surface contact during the charging for determining a secondary electron signal over time; and determining a state information about the first electrical connection depending on an occurrence of a drop or decline in the secondary electron signal. Further described is an apparatus for identifying defective electrical connections of a substrate according to the methods described herein.

### FIELD

The present disclosure relates to methods and apparatuses for identifying defective electrical connections that extend through a substrate, particularly through a packaging substrate, such as an advanced packaging (AP) substrate or a panel-level packaging (PLP) substrate. More particularly, embodiments described herein relate to the contactless testing of electrical connections in a substrate using an electron beam, particularly for identifying and characterizing defects.

### BACKGROUND

In many applications, it is necessary to inspect a substrate to monitor the quality of the substrate. Since defects may occur during the processing of the substrates, e.g. during the coating of the substrates, an inspection of the substrate for reviewing the defects and for monitoring the quality of the displays may be beneficial.

Semiconductor substrates and printed circuit boards for the manufacture of complex microelectronic or micro-mechanic components are typically tested before, during, and/or after manufacturing for determining defects, such as “short defects” or “open defects”, in conductive paths and interconnects extending on or through substrate layers. For example, substrates for the manufacture of complex microelectronic devices may include a plurality of interconnect paths meant for connecting semiconductor chips that are to be mounted on the substrate.

Various methods for testing such components are known. For example, contact pads of a component to be tested may be mechanically contacted with a contact probe, in order to determine whether the component is defective or not. However, since the components and the contact pads are becoming smaller and smaller due to the progressing miniaturization of components, contacting the contact pads with a contact probe may be difficult, and there may even be a risk that the device under test gets damaged during the testing.

The complexity of packaging substrates is increasing and design rules (feature size) are decreasing substantially. Within such substrates, the surface contacts (for later flip chip or other chip mounting) are connected to other surface contacts on the packaging substrate to interconnect semiconductor (or other) devices or chips. Standard methods like electrical-mechanical probing cannot satisfy the requirements of volume production testing, as the throughput decreases (higher number of test points) and contacting reliability decreases (smaller contact size). Beyond the reduced size and the risk of damaging contact pads with a mechanical prober, the topography of the packaging substrates results in difficulties for other test methods, like test methods utilizing capacitive detectors or electrical field detectors, because such methods beneficially have a small mechanical spacing.

Accordingly, it would be beneficial to provide testing methods and testing apparatuses that are suitable for reliably and quickly identifying defects in electrical connections of complex microelectronic devices.

### SUMMARY

In light of the above, methods and apparatuses for identifying defective electrical connections of a substrate are provided according to the independent claims. Further aspects, advantages and beneficial features are apparent from the dependent claims, the description, and the accompanying drawings.

According to one aspect, a method of identifying defective electrical connections of a substrate is provided, the substrate having a first surface contact and a first electrical connection extending from the first surface contact. The method includes placing the substrate on a stage in a vacuum chamber; charging the first surface contact by directing an electron beam on the first surface contact and detecting secondary electrons emitted from the first surface contact during the charging to provide a secondary electron signal over time; and determining a state information about the first electrical connection depending on an occurrence of a drop or decline in the secondary electron signal.

In some embodiments, the first surface contact is very small. In particular, the first surface contact may have a diameter of 60 μm or less, particularly 35 μm or less, or even 10 μm or less. For example, the first surface contact may be formed as a metal pad covered by a solder bump having a diameter of 35 μm or less.

In some embodiments, the substrate is an advanced packaging substrate (AP substrate), a panel-level packaging (PLP) substrate, or a wafer-level packaging (WLP) substrate.

According to another aspect, an apparatus for identifying defective electrical connections of a substrate is provided. The apparatus includes a vacuum chamber that houses a stage for placement of the substrate; an electron source configured to generate an electron beam; a scan deflector for directing the electron beam on a first surface contact for charging the first surface contact; an electron detector configured to detect secondary electrons emitted from the first surface contact during the charging to provide a secondary electron signal over time; and a data processing unit with a memory storing instructions which, when executed, cause the data processing unit to determine a state information about a first electrical connection connected to the first surface contact depending on an occurrence of a drop or decline in the secondary electron signal.

The apparatus may be configured for conducting any of the methods described herein. Specifically, described herein are apparatuses that are configured for conducting any of the methods described herein.

According to another aspect described herein, a method of identifying defective electrical connections of a substrate is provided, the substrate having a first surface contact with a diameter of 35 μm or less and a first electrical connection extending from the first surface contact. The method comprises placing the substrate on a stage in a vacuum chamber; charging the first surface contact by directing an electron beam on the first surface contact and detecting secondary electrons emitted by the first surface contact during the charging for determining a secondary electron signal over time; and determining a state information, particularly a defect information, about the first electrical connection based on a time dependency of the secondary electron signal.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus and methods for manufacturing the apparatuses and devices described herein. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1 shows a schematic view of an apparatus for identifying defective electrical connections according to embodiments described herein;

FIGS. 2A-C schematically illustrate methods of testing electrical connections according to embodiments described herein;

FIG. 3 schematically illustrates a method of identifying defective electrical connections according to embodiments described herein; and

FIG. 4 is a flowchart illustrating a method of identifying defective electrical connections according to embodiments described herein.

### DETAILED DESCRIPTION

Reference will now be made in detail to the various exemplary embodiments, one or more examples of which are illustrated in each figure. Each example is provided by way of explanation and is not meant as a limitation. For example, features illustrated or described as part of one embodiment can be used on or in conjunction with other embodiments to yield yet further embodiments. The intention is that the present disclosure includes such modifications and variations.

Within the following description of the drawings, the same reference numbers refer to same components. Only the differences with respect to the individual embodiments are described. The structures shown in the drawings are not necessarily depicted true to scale but rather serve the better understanding of the embodiments.

The complexity of packaging substrates has been increasing for years, with the aim of reducing the space requirements of semiconductor packages. For reducing the manufacturing costs, packaging techniques were proposed, such as 2.5D ICs, 3D-ICs, and wafer-level packaging (WLP), e.g. fan-out WLP. In WLP techniques, the integrated circuit is packaged before dicing. A “packaging substrate” as used herein relates to a packaging substrate configured for an advanced packaging technique, particularly an WLP-technique or a panel-level-packing (PLP)-technique

“2.5D integrated circuits” (2.5D ICs) and “3D integrated circuits” (3D ICs) combine multiple dies in a single integrated package. Here, two or more dies are placed on a packaging substrate, e.g. on a silicon interposer or a panel-level-packaging substrate. In 2.5D ICs, the dies are placed on the packaging substrate side-by-side, whereas in 3D ICs at least some of the dies are placed on top of each other. The assembly can be packaged as a single component, which reduces costs and size as compared to a conventional 2D circuit board assembly.

A packaging substrate typically includes a plurality of device-to-device electrical interconnect paths meant for providing electrical connections between the chips or dies that are to be placed on the packaging substrate. The device-to-device electrical interconnect paths may extend through a body of the packaging substrate in a complex connection network, vertically (perpendicular to the surface of the packaging substrate) and/or horizontally (parallel to the surface of the packaging substrate) with end points (referred to herein as surface contacts) exposed at the surface of the packaging substrate, e.g. on the top and/or bottom surfaces of the substrate.

An advanced packaging (AP) substrate provides the device-to-device electrical interconnection paths on or within a wafer, such as a silicon wafer. For example, an AP substrate may include Through Silicon Vias (TSVs), e.g., provided in a silicon interposer, other conductor lines extending through the AP substrate. A panel-level-packaging substrate is typically made of a compound material, for example material of a printed circuit board (PCB) or another compound material, including, for example ceramics and glass materials.

Panel-level-packaging substrates are manufactured that are configured for the integration of a plurality devices (e.g., chips/dies that may be heterogeneous, e.g. may have different sizes and configurations) in a single integrated package. Further, AP substrates may be combined on a PLP substrate. A panel-level packaging substrate typically provides sites for a plurality of chips, dies, or AP substrates to be placed on a surface thereof, e.g. on one side thereof or on both sides thereof, as well as a plurality of device-to-device electrical interconnect paths extending through a body of the PLP substrate.

Notably, the size of a panel-level-substrate is not limited to the size of a wafer. For example, a panel-level-substrate may be rectangular or have another shape. Specifically, a panel-level-substrate may provide a surface area larger than the surface area of a typical wafer, e.g., 1000 cm² or more. For example, the panel-level substrate may have a size of 30 cm×30 cm or larger, 60 cm×30 cm or larger, 60 cm×60 cm or larger, or larger than that.

The present disclosure relates to methods and apparatuses for testing substrates, particularly packaging substrates, configured for the integration of a plurality of devices in one integrated package, and including at least one device-to-device electrical interconnect path. According to embodiments of the present disclosure, a test system, test apparatus, or test method may detect specific defects of electrical connections in a packaging substrate, such as discharge defects, leakage defects, or others, e.g., open or short defects. Particularly, the test methods and test systems may provide a contactless testing.

A contact pad size of 60 μm or below or even about 10 μm or below is difficult and even impossible for mechanical probing. Also, the small contact pads must not be damaged by any scratch. Contactless testing is beneficial. The surface contacts of electrical connections that are tested according to embodiments described herein may be particularly small, e.g., with diameters of 35 μm or less. According to embodiments of the present disclosure, e-beam testing and/or e-beam review enables the testing of contact pads with diameters of 60 μm or below, 35 μm or below, or even 10 μm or below.

A “surface contact” may be understood as an end point of an electrical interconnect path (also referred to herein as an “electrical connection”) that is exposed at a surface of the substrate, such that an electron beam can be directed on the surface contact for contactlessly charging or probing the surface contact. A surface contact may be meant for electrically contacting a chip/die that is to be placed on the surface of the substrate, e.g. via soldering. For example, a surface contact may be configured as a solder bump. In particular, the surface contact may include a solder bump with a diameter of 35 μm or less.

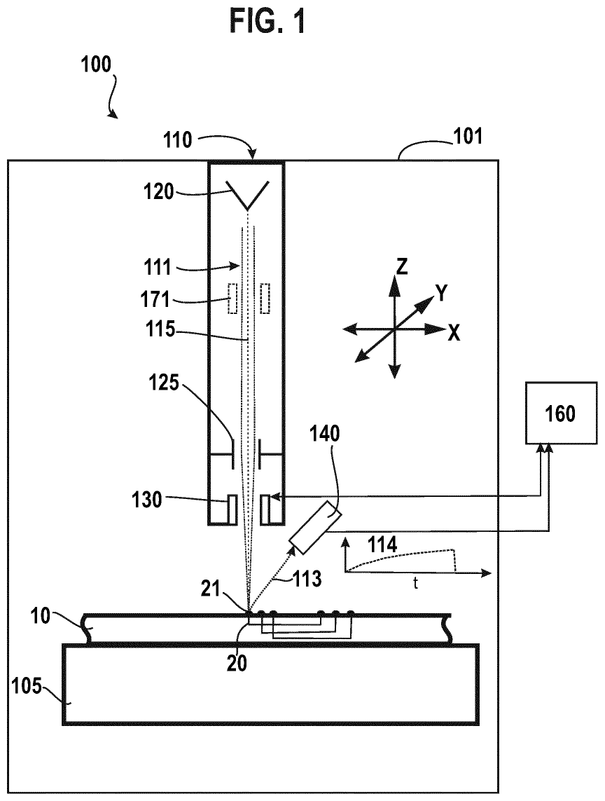

FIG. 1 schematically shows an apparatus 100 for identifying defects in electronic connections, such as interconnect paths and/or via extending through a substrate 10, according to embodiments described herein. The apparatus 100 may include a vacuum chamber 101 that may be a testing chamber specifically configured for testing or that may be one vacuum chamber of a larger vacuum system, e.g. a processing chamber of a substrate manufacturing or processing system. For example, the apparatus may be configured as an in-line inspection apparatus that is integrated in a substrate processing system.

The vacuum chamber 101 may house an electron beam column 110 and a stage 105, e.g. a movable stage, for placing the substrate 10 thereon. The apparatus 100 further includes an electron source 120 configured to generate an electron beam, a scan deflector 130 for deflecting the electron beam to a predetermined position on the substrate, and an electron detector 140 configured to detect secondary electrons emitted from the substrate upon impingement of the electron beam.

As it is schematically shown in FIG. 1, the substrate 10 includes a first surface contact 21 and a first electrical connection 20 extending from the first surface contact 21 through the substrate, e.g. to one or more further surface contacts that may be located on the same surface of the substrate as the first surface contact 21 or that may be located on an opposite substrate surface (not shown in the figures). The substrate 10 may include a plurality of surface contacts and a plurality of electrical connections extending from the plurality of surface contacts, for example 10,000 or more electrical connections, particularly 100,000 or more electrical connections, or even 1,000,000 or more electrical connections. According to methods described herein, the plurality of electrical connections extending from the plurality of surface contacts may be inspected for identifying defective connections.

The electron source 120 is configured to generate an electron beam 111 that propagates along an electron beam path 115 toward the substrate, e.g. a thermal field emitter. The electron beam 111 can be directed, particularly focused, on a predetermined location on the substrate. Specifically, the apparatus 100 may include a scan deflector 130 configured to direct the electron beam 111 on a surface contact, e.g. on the first surface contact 21 as depicted in FIG. 1. By directing the electron beam 111 on a surface contact, the surface contact and the electrical connection that extends from the surface contact can be charged, particularly negatively charged.

In some embodiments, the electron beam 111 can be focused on the surface of the substrate 10, e.g. by a focusing lens 125, particularly a magnetic and/or electrostatic focusing lens. Specifically, the focusing lens 125 may be configured to focus the electron beam 111 on the first surface contact 21 for charging the first surface contact 21 in a targeted way (without charging neighboring areas and/or adjacent surface contacts).

Further beam-optical components 171 may optionally be provided along the electron beam path 115 for influencing the electron beam 111, such as, e.g., a condenser lens and/or an aberration corrector, e.g. a stigmator and/or a chromator.

In some implementations, the electron energy of the electron beam 111 (i.e., the landing energy of the electrons of the electron beam 111 on the substrate surface) may be above the neutral charging point. The “neutral charging point” as used herein refers to an electron energy of the electron beam that does not change the charges on an uncharged surface contact when the electron beam impinges thereon, because the amount of signal electrons emitted from the substrate upon impingement essentially corresponds to the amount of electrons transferred to the surface contact by the electron beam. The neutral charging point may, in some implementations, correspond to an electron energy of the electron beam 111 between 1.5 keV and 3 keV, particularly about 2 keV.

Electrons impinging on the substrate with a landing energy above the neutral charging point may have a reduced probability of generating secondary electrons emitted from the substrate, such that the substrate is negatively charged when hit by an electron beam with an electron energy above the neutral charging point. Electrons impinging on the substrate with a landing energy below the neutral charging point may have an increased probability of generating secondary electrons that leave the substrate, such that the substrate can be discharged when hit by an electron beam with an electron energy below the neutral charging point.

In some embodiments, the electron energy of the electron beam 111 may be 5 keV or more, particularly about 10 keV, particularly an electron energy above the neutral charging point. Therefore, the amount of signal electrons emitted from the substrate upon impingement is typically smaller than the amount of electrons transferred to the substrate by the electron beam 111. Accordingly, negative charges can be transferred to a surface contact by the electron beam 111, such that the surface contact, together with the electrical connection extending therefrom, can be negatively charged. “Charging” as used herein may particularly relate to the application of negative charges, i.e. electrons, to a surface contact to cause a predetermined (negative) electric potential of the electrical connection that extends from the surface contact.

The apparatus 100 further comprises an electron detector 140 configured to detect secondary electrons 113 emitted from the substrate 10, particularly during the impingement of the electron beam 111. The electron detector 140 may be configured to detect the secondary electrons (SEs) emitted during the charging of the first surface contact 21 with the electron beam 111 to provide a secondary electron signal 114 as a function of time during the charging. A “secondary electron signal” or “SE signal” as used herein may refer to the number of secondary electrons emitted by a surface contact as a function of time and detected by the electron detector 140 in the course of the charging of the surface contact. The SE number depends on the surface voltage. Specifically, the secondary electron signal 114 includes information about the time dependency of the surface voltage during the charging. FIG. 1 schematically indicates a secondary electron signal 114 as a graph showing the detected SE yield (x-axis) as a function of time (y-axis) during the charging. The SE yield may be measured at discrete time periods during the charging (e.g., every 100 nm until reaching a saturation value) to provide the secondary electron signal 114 as a (discrete) function of time.

In some embodiments, the electron detector 140 includes an Everhard-Thornley detector. An energy filter for the signal electrons may be arranged in front of the electron detector 140, particularly in front of the Everhard-Thornley detector. The energy filter may include, e.g., a grid electrode configured to be set on a predetermined potential. The energy filter may allow the suppression of low-energy signal electrons. The energy filter may be set for optimized voltage contrast detection. Accordingly, the signal strength detected by the electron detector 140 may depend on the energy of the signal electrons which indicates if a surface contact point is provided at a predetermined electric potential or not.

Notably, if an image of a surface area is taken by a conventional scanning electron microscope, only the SE yield per pixel is generally of interest, not a time dependency of an SE signal during a charging process, which distinguishes embodiments disclosed herein from conventional imaging scanning electron microscopes.

The secondary electron signal 114 generated during the charging with the electron beam 111 is time dependent, because the amount of negative charges on the first surface contact increases during the charging, which increases the secondary electron yield due to the increasingly negative potential of the first surface contact. Further, the temporal behavior of secondary electron signal 114 depends on electrical characteristics of the first electrical connection 20, including the capacitance of the first electrical connection, the cross-capacitance in relation to neighboring electrical connections, leakage defects between adjacent electrical connections, and/or approach points between neighboring contacts that entail a risk of spark discharges therebetween at high potentials. For example, a small-capacitance electrical connection charges up quickly, such that the secondary electron signal 114 rises quickly over time, whereas a large-capacitance electrical connection charges up slowly, such that the secondary electron signal 114 rises slowly over time.

If an electrical connection is fully interrupted due to a defect (i.e., if an “open” defect exists), the capacitance of the respective electrical connection is smaller than expected, which will lead to an unexpectedly quick rise of the secondary electron signal over time. If an electrical connection is shorted to another electrical connection due to a defect (i.e., if a “short” defect exists), the capacitance of the respective electrical connection is larger than expected, which will lead to an unexpectedly slow rise of the secondary electron signals over time during the charging. Therefore, the secondary electron signal generated as a function of time during the charging of a surface contact can provide defect information about the electrical connection that is connected to the surface contact, if it is known how the SE signal of the respective electrical connection in a faultless case would look like. Accordingly, defects such as “open” defects and “short” defects can be determined, for example, by analyzing the gradient of the curve rise of the secondary electron signal 114, particularly by examining whether the gradient is within a predetermined expected range.

Also other specific types and classes of defects may be of interest, including so-called “leakage defects” (e.g., if a first electrical connection is in leakage contact with, i.e. not fully isolated from, another conductor, such that charges can slowly leak away from the first electrical connection, for example if the voltage of the first electrical connection exceeds a threshold value) and/or “discharge defects” or “spark defects” (e.g., if a first electrical connection is not electrically connected to, but in undesired electrical proximity to another conductor, for example due to a defect or crack in a dielectric, leading to a sudden discharge—or “spark”—if the voltage of the first electrical connection exceeds a threshold value). Determining such types and classes of defects is challenging, particularly if the surface contacts are extremely small and cannot be contacted with mechanical probes. Specifically, surface contacts with a diameter of 60 μm or less cannot be reliably contacted with a probing needle for examining whether a sudden discharge or a leakage from a specific surface contact has happened. Surface contacts of some packaging substrates have diameters of 35 μm or less, or even 10 μm or less.

Embodiments described herein particularly relate to the determination of such “discharge defects” and/or “leakage defects” in a contactless way by charging with an electron beam. The testing methods described herein may therefore also be referred to as a “spark test” or a “leakage test” and can also be applied to packaging substrates with small surface contacts of, e.g. 35 μm in diameter or less. A spark test is based on the application of a high voltage on a surface contact in order to determine if the respective electrical connection extending from the surface contact can withstand, or fails by a sudden discharge (spark) or continuous voltage drop (leakage). According to embodiments described herein, both the charging of the surface contacts and the signal detection are done contactlessly by directing an electron beam on the surface contacts and by detecting secondary electrons emitted from the substrate during the charging.

As is schematically depicted in FIG. 1, the first surface contact 21 is charged by directing the electron beam 111 on the first surface contact. During the charging, secondary electrons 113 emitted from the first surface contact are detected for determining a secondary electron signal 114 as a function of time. A state information (or defect information) about the first electrical connection 20 is determined depending on an occurrence of a drop or a decline in the secondary electron signal 114. The state information may be an integrity information about the first electrical connection 20. In particular, the state information may include information as to whether the respective electrical connection includes a leakage defect or a discharge/spark defect.

If an electrical connection can withstand the charging up to a predetermined voltage without a discharge or leakage, the spark test is passed and the respective electrical connection may be classified as “non-defective”, “non-defective” indicating that no leakage or discharge defect could be identified. If an electrical connection cannot withstand the charging up to a predetermined voltage, which can be identified by a drop or decline of the secondary electron signal, the spark test is failed and the respective electrical connection is classified as “defective”, “defective” indicating that a leakage or discharge defect is probably present.

In some embodiments, which can be combined with other embodiments described herein, the first electrical connection is identified as defective when a premature drop or decline in the secondary electron signal 114 is detected. A “premature” drop or decline may refer to a drop or decline in the secondary electron signal that happens earlier than expected during the charging, e.g., before reaching a predetermined charging time or a predetermined charging level. Notably, the charging of a surface contact will always lead to a spark discharge when a sufficiently high potential of the surface contact is reached, such that not every drop or decline in the secondary electron signal is automatically indicative of a defect. However, if the drop or decline of the secondary electron signal happens prematurely, i.e. earlier than expected or before reaching a predetermined voltage or charging level of the respective surface contact, the presence of a discharge or leakage defect can be assumed.

A “drop” of the secondary electron signal may be understood as a jump downward or a sudden or abrupt decrease of the secondary electron signal, which may particularly happen in the event of a spark discharge of the first surface contact or of the first electrical connection extending therefrom. A “decline” of the secondary electron signal may be understood as a slow, continuous or gradual reduction of the secondary electron signal over time, which may particularly happen in the event of a leakage defect, over which the first surface contact and the first electrical connection extending therefrom slowly lose charges.

In particular, in some embodiments, a discharge or spark defect of the first electrical connection may be identified in the event of a sudden drop in the secondary electron signal 114 before reaching a predetermined charging time or charging level. The predetermined charging time may be defined in advance, e.g. depending on the brightness or beam current of the electron beam 111 that is directed on the first surface contact. As a matter of fact, the potential of the first surface contact increases during the charging, because negative charges of the electron beam accumulate on the first surface contact, and a high brightness or a high beam current of the electron beam leads to a quicker increase of the voltage. The predetermined charging time may be defined such that the first surface contact—after charging over the predetermined charging time—is charged up to a maximum potential, which the first surface contact should be able to withstand without a discharge or leakage. The predetermined charging level may refer to the maximum potential or voltage of the first surface contact, which the first surface contact should be able to withstand without a discharge or leakage. The predetermined charging level can be expressed in terms of a predetermined charging time (that depends on the beam current of the electron beam) or in terms of a predetermined level (strength) of the secondary electron signal that should be reachable without a discharge.

In some embodiments, which can be combined with other embodiments described herein, a leakage defect of the first electrical connection 20 is identified in the event of a gradual decline in the secondary electron signal 114 before reaching a predetermined charging time or charging level. In other words, while a premature sudden drop of the secondary electron signal may be identified as being caused by a discharge or spark defect, a slow or gradual decline of the secondary electron signal may be identified as being caused by a leakage defect.

Alternatively or additionally, a leakage defect of the first electrical connection 20 may be identified in the event of a decrease in the secondary electron signal 114 that is stronger than a given threshold value when the charging of the first surface contact is continued after a charging pause. In particular, the first surface contact may be charged with the first electron beam over an initial charging time, until reaching a specific level of the determined secondary electron signal 114. The charging of the first surface contact may then be paused, and continued after the charging pause. If—after the restart of the charging—the level of the secondary electron signal has decreased stronger than expected, i.e., if the decrease is stronger than a given threshold value, a leakage defect may be determined, because the first surface contact and the first electrical connection have lost too many charges during the charging pause, presumably over a leakage contact.

In some embodiments, which can be combined with other embodiments described herein, the first electrical connection 20 may be identified as non-defective when the secondary electron signal 114 rises continuously with a gradient in a predetermined range at least up to a predetermined charging time or a predetermined charging level. If the gradient of the secondary electron signal leaves the predetermined range at least temporarily, e.g. in the event of a drop, decrease, or decline that happens before reaching a predetermined charging level or charging time, the first electrical connection may be identified as defective.

In some embodiments, the predetermined charging time or the predetermined charging level may be predefined in advance, and the charging of the first surface contact may be carried out over the predetermined charging time or until reaching the predetermined charging level (unless a signal drop happens already earlier). Specifically, the electron beam 111 may be focused on the first surface contact over the predetermined charging time and may then be deflected away from the first surface contact or may be turned off or blanked. The first electrical connection 20 may be identified as defective, when a drop or decline in the secondary electron signal 114 is detected before reaching the predetermined charging time or charging level.

As it is schematically depicted in FIG. 1, the apparatus 100 includes a data processing unit 160, such as a computer, with a memory storing instructions which, when executed, cause the data processing unit to determine a state information about the first electrical connection 20 extending from the first surface contact 21 depending on an occurrence of a drop or decline in the secondary electron signal 114 that is provided by the electron detector 140.

In particular, the data processing unit 160 may be configured to identify the first electrical connection as defective when detecting a drop or decline in the first secondary electron signal before reaching the predetermined charging time or charging level. For example, a discharge or spark defect of the first electrical connection may be identified in the event of a sudden drop in the first secondary electron signal before reaching the predetermined charging time or charging level. A sudden drop may, for example, be defined as a drop in the signal strength of the SE signal by 50% or more within a predetermined time interval that is indicative of a spark discharge.

A leakage defect of the first electrical connection may be identified in the event of a gradual decline of the first secondary electron signal before reaching the predetermined charging time or charging level. A gradual decline may, for example, be defined as a slow and/or continuous decrease of the strength of the secondary electron signal that can be measured either during continuous charging or that can be measured after a charging pause as a decline of the secondary electron signal that is stronger than a predetermined threshold (e.g. >10% of a previous signal strength, depending on the length of the charging pause) when continuing the charging after the charging pause.

In some embodiments, which can be combined with other embodiments described herein, the substrate has a plurality of surface contacts with a respective electrical connection extending therefrom, particularly 10,000 or more, 100,000 or more, or even 1,000,000 or more surface contacts, which may be successively tested in accordance with the testing methods described herein. In particular, each of the plurality of surface contacts may be tested in analogy to the testing of the first surface contact described above, i.e., by conducting a contactless spark or leakage test. Accordingly, a plurality of electrical connections can be tested in succession by deflecting the electron beam on a surface contact that is connected to the respective electrical connection, by monitoring the SE signal as a function of time during the charging, and by analyzing the SE signal in accordance with the methods described herein for identifying potential drops and/or declines in the SE signals indicative of specific defects.

In some implementations, a scan controller is provided. The scan controller may be configured to sequentially direct the electron beam with the scan deflector 130 to the plurality of surface contacts for charging and testing the respective electrical connections extending from the plurality of surface contacts.

Notably, also additional tests can be applied on the plurality of surface contacts in addition to the spark and leakage test described above. For example, an initial gradient or shape of the secondary electron signal 114 provided as a function of time can be analyzed for determining other defects, such as “open” defects and/or “short” defects. Alternatively or additionally, other surface contacts that should be connected or should be separated from a charged surface contact may be probed with the charging beam or with a probing electron beam, in order to determine potential “open” defects and/or “short” defects of the electrical connections. An electrical detection that is classified as “non-defective” after conducting (only) a spark test may not necessarily be without any defect, and further tests for identifying possible further defect types may be conducted.

In some embodiments, the substrate 10 is an advanced packaging (AP) substrate or a panel-level packaging (PLP) substrate configured to provide a multi-device in-package-interconnection, the first electrical connection being a device-to-device electrical interconnect path. For example, the substrate may be a panel level packaging (PLP) substrate, a wafer level packaging (WLP) substrate, a micro-LED substrate, or an advanced packaging (AP) substrate. The packaging substrate may include a plurality of 1,000,000 or more surface contacts with respective electrical connections extending therefrom, which may all be tested in succession. The device-to-device electrical interconnect path may extend between two or more surface contacts and/or may be configured to connect two or more devices or chips that are to be placed on the packaging substrate, respectively.

In some implementations, the plurality of surface contacts are distributed over a surface area of the substrate or a surface sub-area of the substrate of 16 cm² or more, particularly 25 cm² or more, more particularly 100 cm² or more, or even 225 cm² or more. The method may include successively deflecting the electron beam 111 with the scan deflector 130 on the plurality of surface contacts for successively charging and testing the electrical connections extending therefrom in accordance with the methods described herein, particularly exclusively by deflecting the electron beam without a stage movement.

In some embodiments, the scan deflector 130 may provide a deflection area (i.e., a surface area of the substrate that can be reached by deflecting the electron beam with the scan deflector 130, without a movement of stage) of 16 cm² or more, particularly 100 cm² or more, more particularly 225 cm² or more. A large deflection area allows a quick and accurate testing of a large number of electrical connections, since there is no need to move the substrate for testing the plurality of electrical connections. In particular, at least one complete chip site on the surface of the packaging substrate can be tested by deflecting the electron beam on the surface contacts of the chip site, without a stage movement.

In some embodiments, which can be combined with other embodiments described herein, the first surface contact 21 and/or the plurality of surface contacts may be very small, particularly having a diameter of 60 μm or less, particularly 35 μm or less, more particularly 10 μm or less, respectively. For example, the first surface contact 21 and/or the plurality of surface contacts may be formed as a metal pad covered by a solder bump, the solder bump having a diameter of 35 μm or less. For charging a surface contact, the electron beam may be directed on the respective solder bump, respectively. In some embodiments, the first surface contact 21 and/or the plurality of surface contacts on which the electron beam is directed may have a three-dimensional topography, particularly a substantially semi-spherical shape, respectively.

In some embodiments, which can be combined with other embodiments described herein, the apparatus further includes a discharging device for discharging at least a portion of the substrate, particularly for discharging the first surface contact 21 before and/or after the charging thereof. For example, the first surface contact 21 can be discharged before the charging, in order to ensure that the charging starts from a predetermined electrical potential of the first surface contact. For example, if a plurality of charges were already present on the first surface contact before the charging, a spark discharge or signal decrease would happen earlier than expected due to the existing charges which influence the SE yield. Therefore, discharging the first surface contact before the charging and inspection may be beneficial. In particular, each of a plurality of surface contacts may be discharged before the charging and inspection thereof.

Alternatively or additionally, the first surface contact may be discharged after the charging and inspection of the first surface contact. The discharging after the inspection reduces or avoids an accumulation of charges on the surface of the substrate, which may distort the results of subsequent inspection measurements. In particularly, charges on the surface of the substrate may deflect the electron beam and/or may affect the SE signal that is detected by the electron detector, e.g. if a charged surface contact is arranged in the vicinity of the first surface contact being currently tested. Therefore, discharging the first surface contact after the charging and testing may be beneficial. In particular, each of a plurality of surface contacts may be discharged after the charging and inspection thereof. In particular, each surface contact of a plurality of surface contacts may be discharged both before and after the inspection.

In some embodiments, the discharging device may include any of a second electron source configured to generate a second electron beam for discharging, an electron flood gun configured to discharge a large surface area of the substrate, and/or a UV discharging lamp. The second electron source may be configured to generate the second electron beam having a second electron energy different from the electron energy of the electron beam 111. In particular, the second electron energy of the second electron beam may be below the neutral charging point, e.g. 2 keV or less, such as about 1.5 keV, such that the second electron beam can be used for removing charges from the substrate.

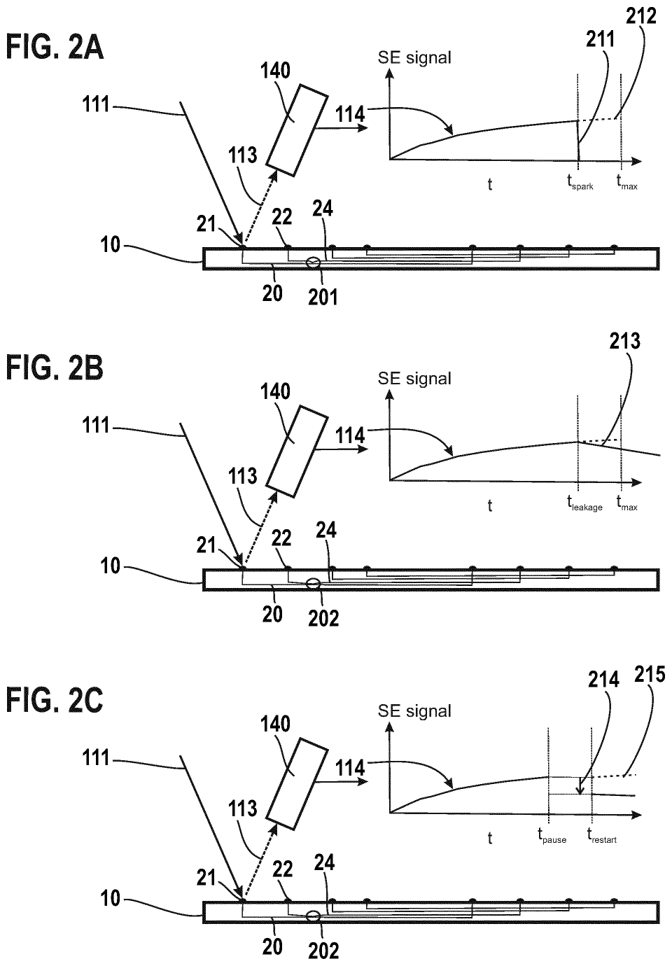

FIGS. 2A-C schematically illustrate methods of identifying defective electrical connections of a substrate according to embodiments described herein. FIG. 2A shows the testing of a first electrical connection 20 extending from a first surface contact 21, wherein the first electrical connection 20 is defective and has a discharge defect 201. Specifically, the first electrical connection 20 is not electrically connected to, but in undesired close proximity to the second electrical connection 24, e.g. due to a defect, crack, or hole in the dielectric material between the electrical connection, which is referred to herein as a discharge defect 201 or spark defect. Also contaminations and manufacturing inaccuracies may lead to spark defects, i.e. defects that could cause spark discharges during operation when applying electrical voltages to the respective electrical connections.

The electron beam 111 is directed on the first surface contact 21 for charging the first surface contact 21, and secondary electrons 113 emitted from the first surface contact are detected with the electron detector 140 during the charging. The charging may be conducted up to a predetermined charging time tₘₐₓ that may be preset in advance based on the electron current of the electron beam 111 and based on the potential of the first electrical connection 20 that needs to be reachable without a spark discharge. The secondary electron signal 114 that corresponds to the SE yield as a function of time during the charging is detected and is monitored. In the example of FIG. 2A, a sudden drop (see at 211 in FIG. 2A) in the secondary electron signal 114 is detected at a discharge time tₛₚₐᵣₖ that is smaller than the predetermined charging time tₘₐₓ, such that a spark defect or discharge defect 201 of the first electrical connection 20 is identified.

Otherwise, if the secondary electron signal 114 continues to rise with a gradient in a predetermined range at least up to the predetermined charging time tₘₐₓ, particularly without a drop or decline (see curve section 212 shown as a dashed line in FIG. 2A), the first electrical connection passes the spark test and may be classified as “non-defective”.

Thereafter, a second surface contact 22 and a second electrical connection 24 extending therefrom may be analogously tested, optionally after discharging the first surface contact with a discharging device.

FIG. 2B shows the testing of a first electrical connection 20 extending from a first surface contact 21, wherein the first electrical connection 20 is defective and has a leakage defect 202. Specifically, the first electrical connection 20 is in leakage contact and hence not fully electrically isolated from an adjacent second electrical connection 24, such that charges can slowly leak away from the first electrical connection to the second electrical connection. A “leakage defect” is typically distinguished from a “short defect”, which is a (full) electrical contact between conductors that should actually be electrically separated.

The electron beam 111 is directed on the first surface contact 21 for charging the first surface contact 21, and secondary electrons 113 emitted from the first surface contact are detected with the electron detector 140 during the charging. The charging may be conducted up to a predetermined charging time tₘₐₓ that may be preset in advance based on the electron current of the electron beam 111 and based on the potential of the first electrical connection 20 that should preferably be reachable without occurrence of a leakage. The secondary electron signal 114 that corresponds to the SE yield as a function of time during the charging is detected and is monitored. In the example of FIG. 2B, a gradual and continuous decline (see at 213 in FIG. 2B) in the secondary electron signal 114 is detected at a leakage time t_{leakage} that is smaller than the predetermined charging time tₘₐₓ, such that a leakage defect 202 of the first electrical connection 20 can be identified.

FIG. 2C shows the testing of a first electrical connection 20 extending from a first surface contact 21, wherein the first electrical connection 20 is defective and has a leakage defect 202.

The electron beam 111 is directed on the first surface contact 21 for charging the first surface contact 21, and secondary electrons 113 emitted from the first surface contact are detected with the electron detector 140 during the charging. The charging may be conducted over an initial charging time tₚₐᵤₛₑ. after which the charging may be paused. After a predetermined charging pause, the charging of the first surface contact with the electron beam 111 may continue at a restart time tᵣₑₛₜₐᵣₜ. The secondary electron signal 114 that corresponds to the SE yield as a function of time during the charging may be detected and monitored. In the example of FIG. 2C, a decrease (see arrow 214 in FIG. 2C) in the secondary electron signal 114 with respect to a previous signal level is detected after the charging pause. The decrease may be stronger than a given threshold value. Accordingly, a leakage defect 202 of the first electrical connection 20 is identified.

On the other hand, in the absence of a leakage defect, the strength of the secondary electron signal directly after the charging pause would essentially correspond to the strength of the secondary electron signal directly before the charging pause (see curve section 215 shown as a dashed line in FIG. 2C).

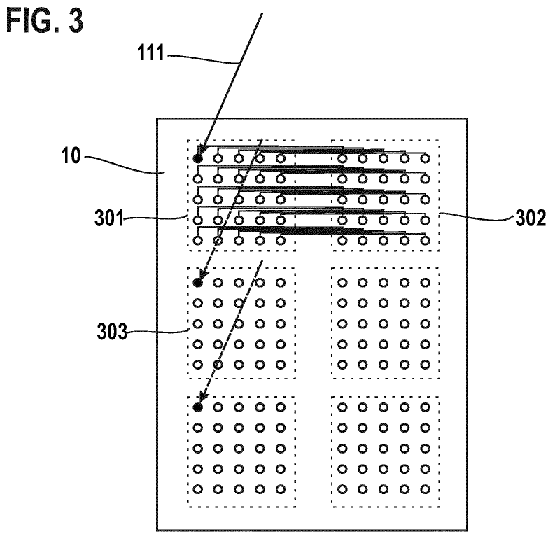

FIG. 3 schematically illustrates a method of identifying defective electrical connections of a substrate 10 according to embodiments described herein. The substrate 10 may be a PLP substrate or an AP substrate including a plurality of chip sites 301, 302, 303 each configured for the placement of a respective chip, and 1,000 or more device-to-device electrical interconnect paths may extend from each chip site to one or more other chip sites through the PLP substrate. For example, the substrate may include two, three or more pairs of associated chip sites, and 1,000 or more device-to-device electrical interconnect paths (having optionally exactly two surface contact points, namely one in each chip site of a pair) may extend between the chip sites of each pair through the packaging substrate, as it is schematically depicted in FIG. 3 for the upper pair of chip sites. In particular, the substrate 10 may be a packaging substrate with a plurality of extremely small surface contacts having respective diameters of 60 μm or less, 35 μm or less, or even 10 μm or less, that may optionally be formed as solder bumps.

Optionally, each surface contact of the plurality of surface contacts located at a first chip site 301 may have a corresponding position identifier. Surface contacts arranged at corresponding positions at different chip sites may have corresponding position identifiers. For example, the three surface contacts illustrated as black circles in FIG. 3 that are respectively arranged at upper left corners of respective chip sites may have corresponding position identifiers, since the electrical characteristics of electrical connections extending therefrom may be similar or essentially identical. Alternatively or additionally, each surface contact of a specific substrate type may have a respective position identifier. Secondary electron signals generated upon charging of surface contacts having the same position identifier may have a generally similar or identical behavior as a function of time during charging thereof.

In some embodiments, the predetermined charging time tₘₐₓ up to which a surface contact should be able to withstand a spark discharge and/or leakage may be defined depending on the position identifier of the respective surface contact. Grouping surface contacts and respective electrical connections according to respective electrical properties that result in similar or identical SE signals upon charging, each group having a respective position identifier, may improve the reliability of the determined state information.

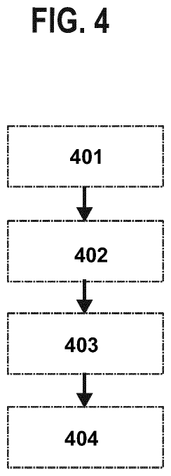

FIG. 4 is a flowchart illustrating a method of identifying defective electrical connections according to embodiments described herein.

In box 401, a first surface contact being tested is charged by directing an electron beam on the first surface contact, and secondary electrons emitted from the first surface contact are detected during the charging for determining a secondary electron signal as a function of time. In particular, the electron beam may be focused on the first surface contact with a focusing lens. In some embodiments, the first surface contact has a diameter of 60 μm or smaller.

In box 402, a state information about the first electrical connection is determined depending on an occurrence of a drop or decline in the first secondary electron signal. Specifically, the first electrical connection may be identified as defective when a premature drop or decline in the first secondary electron signal is detected in the course of a continuous charging of the first surface contact, or when the level of the secondary electron signal has decreased stronger than appropriate after a charging pause.

The method may proceed in box 403 by deflecting the electron beam to impinge on a second surface contact for charging and testing a second electrical connection that extends from the second surface contact. The second electrical connection may be inspected in analogy to the first electrical connection.

The method may proceed in box 404 by successively deflecting the electron beam to impinge on a plurality of further surface contacts for charging and testing a plurality of further electrical connections that extend from the plurality of further surface contacts.

Optionally, any of the surface contacts may be discharged before and/or after the charging, in order to avoid an accumulation of charges on the substrate that may negatively affect the defect detection.

Optionally, the secondary electron signals may be further analyzed for detecting potential further defects of the respective electrical connections, such as “short” defects and/or “open” defects. Specifically, a deviation of a measured initial gradient or shape of a secondary electron signal from an expected gradient (rise) during the charging may be indicative of a “short” defect or an “open” defect. In some embodiments, the secondary electron signal may be provided as an input to a trained computational model that is adapted to identify defect information based on the input and to provide defect information as an output.

According to another aspect described herein, and particularly in the case of very small surface contacts having diameters of 35 μm or less, the state information about the first electrical connection is determined more generally based on the time dependency of the secondary electron signal, i.e., not necessarily depending on an occurrence of a drop or decline in the secondary electron signal. Rather, the state information about the electrical connections may be determined depending (additionally or exclusively) on other characteristics in the temporal behavior of the SE signal detected during the charging. For example, an “open” defect may be detected if a gradient in an initial section of the SE signal rises more steeply than expected, and/or a “short” defect may be detected if a gradient in an initial section of the SE signal rises more flatly than expected. Alternatively or additionally, as described herein, a drop or decline in a subsequent section of the SE signal, before reaching a predetermined maximum charging time, may be indicative of a “spark” defect or “leakage” defect. A plurality of defects may be detected and classified by monitoring and analyzing the temporal behavior of the SE signal detected during the charging, including the analysis of rising signal sections and/or drop or decline sections in the SE signal.

Methods and apparatuses described herein enable a contactless spark/leakage test for determining whether electrical connections of a substrate have a spark defect or a leakage defect. Since both the charging and the signal detection are conducted contactlessly by an electron beam and by detecting secondary electrons, the processes described herein does not damage the substrate and the surface contacts provided thereon, which is different from tests that rely on mechanical contacting probes. The tests described herein can be performed on very small surface contacts, such as 35 μm, 10 μm or smaller. The tests have a high sensitivity. In the methods described herein, the surface contacts can be charged—if appropriate—up to a potential corresponding to the energy of the electrons of the charging electron beam, e.g., up to 10 kV or more if the electron landing energy is 10 keV or more.

Further, testing with an electron beam is quicker than testing with a flying mechanical prober. The methods described herein are also scalable to yet smaller dimensions, if the technical development moves toward yet smaller structures to be tested.

While the foregoing is directed to some embodiments, other and further embodiments may be devised without departing from the basic scope thereof, and the scope thereof is determined by the claims that follow.

What is claimed is:

1. A method of identifying defective electrical connections of a substrate, the substrate having a first surface contact and a first electrical connection extending from the first surface contact, the method comprising:
placing the substrate on a stage in a vacuum chamber;
charging the first surface contact by directing an electron beam on the first surface contact and detecting secondary electrons emitted from the first surface contact during the charging for determining a secondary electron signal over time; and
determining a state information about the first electrical connection depending on an occurrence of a drop or decline in the secondary electron signal.

2. The method of claim 1, wherein the first electrical connection is identified as defective when a premature drop or decline in the secondary electron signal is detected.

3. The method of claim 1, wherein a discharge defect of the first electrical connection is identified in the event of a sudden drop in the secondary electron signal before reaching a predetermined charging time (tₘₐₓ) or charging level.

4. The method of claim 1, wherein a leakage defect of the first electrical connection is identified in the event of a gradual decline in the secondary electron signal before reaching a predetermined charging time (tₘₐₓ) or charging level, and/or
wherein a leakage defect of the first electrical connection is identified in the event of a decrease in the secondary electron signal that is stronger than a given threshold value when the charging is continued after a charging pause.

5. The method of claim 1, wherein the first electrical connection is identified as non-defective when the secondary electron signal continuously rises with a gradient in a predetermined range at least up to a predetermined charging time (tₘₐₓ) or charging level.

6. The method of claim 1, further comprising defining a predetermined charging time (tₘₐₓ) or charging level, wherein the first electrical connection is identified as defective when a drop or decline in the secondary electron signal is detected before reaching the predetermined charging time or charging level.

7. The method of claim 1, wherein the substrate has a plurality of surface contacts with a respective electrical connection extending therefrom, and the plurality of surface contacts are successively charged by directing the electron beam thereon for identifying state information about the respective electrical connection extending therefrom.

8. The method of claim 7, wherein the plurality of surface contacts are distributed over a surface area of the substrate of at least 16 cm², the method further comprising deflecting the electron beam with a scan deflector on the plurality of surface contacts for successively charging the plurality of surface contacts.

9. The method of claim 1, wherein the substrate is a packaging substrate, particularly an advanced packaging substrate or a panel-level packaging substrate, and the first electrical connection is a device-to-device electrical interconnect path extending between two or more surface contacts and configured to connect devices or chips.

10. The method of claim 1, wherein the electron beam is focused on the first surface contact for charging the first surface contact.

11. The method of claim 1, wherein the first surface contact has a diameter of 60 μm or less.

12. The method of claim 1, further comprising energy filtering the secondary electrons.

13. An apparatus for identifying defective electrical connections of a substrate, comprising:
a vacuum chamber that houses a stage for placement of the substrate;
an electron source configured to generate an electron beam;
a scan deflector for directing the electron beam on a first surface contact for charging the first surface contact;
an electron detector configured to detect secondary electrons emitted from the first surface contact during the charging to provide a secondary electron signal over time; and
a data processing unit with a memory storing instructions which, when executed, cause the data processing unit to determine a state information about a first electrical connection connected to the first surface contact depending on an occurrence of a drop or decline in the secondary electron signal.

14. The apparatus of claim 13, wherein the data processing unit identifies the first electrical connection as defective when detecting a drop or decline in the secondary electron signal before reaching a predetermined charging time or charging level.

15. The apparatus of claim 13, wherein the scan deflector is configured to provide a deflection area of 16 cm² or more.

16. The apparatus of claim 13, further comprising a discharging device for discharging at least a portion of the substrate.

17. The apparatus of claim 13, wherein the electron detector comprises:
an Everhard-Thornley detector; and
an energy filter for the secondary electrons in front of the Everhard-Thornley detector.

18. The apparatus of claim 13, further comprising:
a scan controller configured to sequentially direct the electron beam to a plurality of surface contacts for testing electrical connections extending from the plurality of surface contacts.

19. The apparatus of claim 13 that is configured to perform a method of claim 1.

20. A method of identifying defective electrical connections of a substrate, the substrate having a first surface contact with a diameter of 35 μm or less and a first electrical connection extending from the first surface contact, the method comprising:
placing the substrate on a stage in a vacuum chamber;
charging the first surface contact by directing an electron beam on the first surface contact and detecting secondary electrons emitted by the first surface contact during the charging for determining a secondary electron signal over time; and
determining a state information about the first electrical connection based on a time dependency of the secondary electron signal.
